(19) United States
(12) Patent Application Publication
(10) Pub. No.: US 2026/0114282 A1
(43) Pub. Date: Apr. 23, 2026

(54) SEMICONDUCTOR DEVICE

(71) Applicant: SAMSUNG ELECTRONICS CO., LTD., Suwon-si, (KR)

(72) Inventors: Jaeyeong Jo, Suwon-si (KR); Seongyun Baek, Suwon-si (KR); Jinho Kang, Suwon-si (KR); Youngseok Hong, Suwon-si (KR)

(21) Appl. No.: 19/196,256

(22) Filed: May 1, 2025

(30) Foreign Application Priority Data
Oct. 21, 2024 (KR) 10-2024-0144276

(51) Int. Cl. H01L 23/433; H01L 23/00; H01L 23/427; H01L 25/18; H10B 80/00; H10D 80/30

(52) U.S. Cl. CPC H10W 40/77; H10W 40/73; H10W 90/00; H10B 80/00; H10D 80/30; H10W 90/736

(57) ABSTRACT

A semiconductor device includes a case defining an internal space, a support bracket configured to slide within the internal space along a first direction from a first end portion of the case toward a second end portion of the case, a substrate on a surface of the support bracket, one or more semiconductor elements mounted on the substrate, a heat dissipation member between an inner surface of the case and the one or more semiconductor elements, and one or more inclined surfaces within the case. The one or more inclined surfaces is configured to, based on the support bracket sliding in the internal space along the first direction on the one or more inclined surfaces, move the surface of the support bracket toward the inner surface of the case that faces the surface of the support bracket.

### CROSS-REFERENCE TO RELATED APPLICATION(S)

This application claims the benefit of Korean Patent Application No. 10-2024-0144276, filed in the Korean Intellectual Property Office on Oct. 21, 2024, the disclosure of which is incorporated herein by reference in its entirety.

### BACKGROUND

As electronic products have increasingly smaller sizes and higher performance, thermal stability in electronic products is desired. For example, for electronic products (e.g., semiconductor device) including multiple semiconductor elements such as solid-state drive or solid-state disk (SSD), a smartphone, and a laptop, technologies are being developed to discharge heat generated in an internal electronic element through a heat sink.

### SUMMARY

In general, the present disclosure is directed toward a semiconductor device having excellent thermal stability as well as superior assemblability and processability.

According to some implementations, the present disclosure is directed to a semiconductor device that includes a case defining an internal space, a support bracket configured to slide within the internal space along a first direction from a first end portion of the case toward a second end portion of the case, a substrate on a surface of the support bracket, one or more semiconductor elements mounted on the substrate, a heat dissipation member between an inner surface of the case and the one or more semiconductor elements, and one or more inclined surfaces within the case, wherein the one or more inclined surfaces is configured to, based on the support bracket sliding in the internal space along the first direction on the one or more inclined surfaces, move the surface of the support bracket toward the inner surface of the case that faces the surface of the support bracket.

According to some implementations, the present disclosure is directed to a semiconductor device that includes a substrate, one or more semiconductor elements mounted on the substrate, a support bracket on which the substrate is mounted, a case configured to accommodate the support bracket, a heat dissipation member between an inner surface of the case and the one or more semiconductor elements, and an inclined surface within the case, the inclined surface being sloped relative to a lower surface of the support bracket, and the support bracket may be configured to slide from a first position spaced apart from the inclined surface to a second position in contact with the inclined surface, and the heat dissipation member is spaced apart from the case based on the support bracket being at the first position, and the heat dissipation member may be in contact with the case based on the support bracket being at the second position.

According to some implementations, the present disclosure is directed to a semiconductor device that includes a substrate, a first semiconductor element and a second semiconductor element mounted along a first direction on the substrate, a support bracket on which the substrate is mounted, the support bracket including a first pressing part under the first semiconductor element and a second pressing part under the second semiconductor element, a case having an opening provided at a side and into which the support bracket is configured to be inserted through the opening in the first direction, a heat dissipation member having a first surface in contact with the first semiconductor element and the second semiconductor element and a second surface in contact with the case, a first inclined surface within the case, the first inclined surface configured to move the first pressing part of the support bracket, and a second inclined surface within the case, the second inclined surface configured to move the second pressing part of the support bracket.

### BRIEF DESCRIPTION OF THE DRAWINGS

Example implementations will be more clearly understood from the following detailed description, taken in conjunction with the accompanying drawings.

FIG. 1 is a perspective view of an example of a semiconductor device according to some implementations.

FIG. 2 is an exploded perspective view of an example of an semiconductor device according to some implementations.

FIG. 3 is a cross-sectional view showing an example of a state before a support bracket is coupled to a case in a semiconductor device according to some implementations.

FIG. 4 is a cross-sectional view showing an example of a state in which a support bracket is coupled to a case in a semiconductor device according to some implementations.

FIG. 5 is a cross-sectional view of an example of a semiconductor device according to some implementations.

FIG. 6 is a cross-sectional view of an example of a semiconductor device according to some implementations.

FIG. 7 is an exploded perspective view of an example of a semiconductor device according to some implementations.

FIG. 8 is a reference diagram illustrating an example of an arrangement of a pressing part and an inclined surface according to some implementations.

FIG. 9 is a cross-sectional view of an example of a state before a support bracket is coupled to a case in a semiconductor device according to some implementations.

FIG. 10 is a cross-sectional view of an example of a state in which a support bracket is coupled to a case in a semiconductor device according to some implementations.

FIG. 11 illustrates a portion of a cross-sectional view of an example of an auxiliary bracket included in a semiconductor device according to some implementations.

FIG. 12 illustrates a portion of a cross-sectional view of an example of a semiconductor device according to some implementations.

### DETAILED DESCRIPTION

Hereinafter, example implementations will be explained in detail with reference to the accompanying drawings.

In the present disclosure, a singular expression includes a plural expression unless apparently otherwise defined by context. It should be understood that terms such as “comprise or include” and “consist of” are intended to indicate the presence of a feature, a number, a step, an operation, an element, a component, or a combination thereof which are described in the present disclosure and not intended to previously exclude the possibility of the presence or addition of one or more other features, numbers, steps, operations, elements, components, or combinations thereof.

In addition, expressions such as upper side, upper portion, above, lower side, lower portion, below, side surface, front surface, and rear surface hereinafter are represented based on a direction illustrated in a drawing and may be represented otherwise when the direction of a corresponding object changes. The shape or size of elements in drawings may be exaggerated for clearer description.

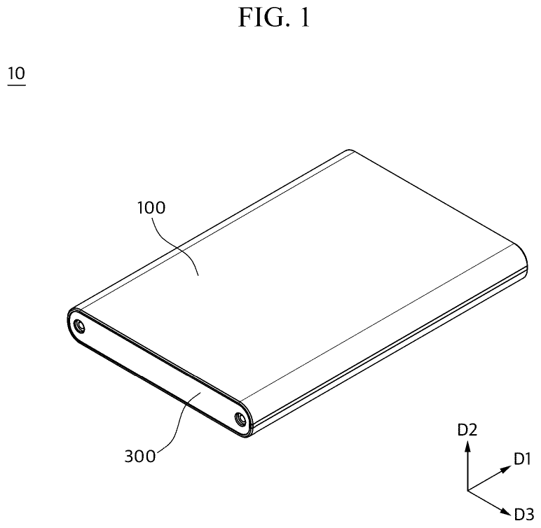

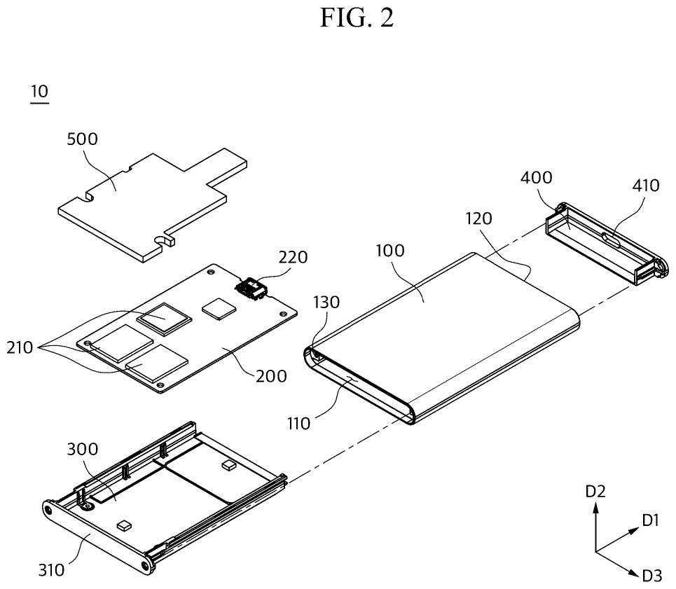

FIG. 1 is a perspective view of an example of a semiconductor device according to some implementations. FIG. 2 is an exploded perspective view of the semiconductor device according to some implementations.

In FIGS. 1 and 2, a semiconductor device 10 may include a substrate 200 on which one or more electronic elements 210 are mounted, a heat dissipation member 500 for heat dissipation of the electronic elements 210, and a case 100 that accommodates the substrate 200 and the heat dissipation member 500.

In some implementations, the semiconductor device 10 may be a memory device that may store data. For example, the semiconductor device 10 may be a portable solid-state drive or solid-state disk (SSD) that a user may carry and use. In some implementations, the semiconductor device 10 may be a memory device fixed to an external device.

In FIG. 2, the one or more electronic elements 210 may be disposed on the substrate 200 included in the semiconductor device 10. For example, the plurality of electronic elements 210 may be disposed at different positions on the substrate 200. In some implementations, at least one of the plurality of electronic elements 210 disposed on the substrate 200 may be a semiconductor package including a semiconductor element or a plurality of semiconductor elements. For example, the semiconductor element may include a non-volatile memory chip, a buffer memory chip, or a passive element. The non-volatile memory chip may include input/output pads that input and output signals and may be electrically connected to the substrate 200. The non-volatile memory chip may be, for example, a NAND or vertical NAND (VNAND) flash memory chip. The buffer memory chip may be a volatile memory chip and may be, for example, a dynamic random access memory (DRAM), phase-change random access memory (PRAM), resistive random access memory (RRAM), ferroelectric random access memory (FeRAM), or magnetic random access memory (MRAM) chip. The passive element may include at least one of a resistor, a capacitor, an inductor, a thermistor, an oscillator, a ferrite bead, an antenna, a varistor, and a crystal. However, the passive element is not limited thereto and may also be any other passive elements.

In some implementations, the plurality of semiconductor elements disposed on the substrate 200 may be different kinds of elements. For example, one of the plurality of semiconductor elements may be the non-volatile memory chip and another may be the buffer memory chip.

In FIG. 2, at least one of the plurality of electronic elements 210 disposed on the substrate 200 may be a controller that may control the semiconductor element. The controller may include a central processing unit (CPU), an internal memory, a buffer memory control unit, a host interface, and a flash interface. The controller may be electrically connected to the semiconductor element. The controller may include a program through which signals may be transmitted to and received from the external device in a manner according to a serial advanced technology attachment (SATA) standard, a parallel advanced technology attachment (PATA) standard, or a small computer system interface (SCSI) standard. Here, the SATA standard may encompass all standards in a SATA family, such as SATA-1, SATA-2, SATA-3, and external SATA (e-SATA). The PATA standard may encompass all standards in an integrated drive electronics (IDE) family, such as IDE and enhanced-IDE (E-IDE).

In some implementations, at least one of the plurality of electronic elements 210 disposed on the substrate 200 may be a communication chip for signal transfer between the semiconductor element and the external device or a sensor chip that may monitor a state of the semiconductor element.

The plurality of electronic elements 210 disposed on the substrate 200 may have different thicknesses from each other. Here, the “thickness” of the electronic elements 210 may refer to a length of the substrate 200 in a second direction (D2 direction) of the FIGS. 1 and 2.

The number, size, thickness, and arrangement of the electronic elements 210 illustrated in FIGS. 1 and 2 are merely examples and the present disclosure is not limited thereto.

In FIG. 2, the substrate 200 may be a printed circuit board (PCB) in which a base layer and a wiring layer are formed. For example, the substrate 200 may be a double-sided PCB or a multi-layer PCB. The wiring layer of the substrate 200 may include a conductive material, for example, aluminum (Al), copper (Cu), nickel (Ni), or tungsten (W). The plurality of electronic elements 210 mounted on the substrate 200 may be mutually electrically connected through the wiring layer of the substrate 200.

The substrate 200 may include a connector 220 at a side to be connected to the external device. The connector 220 may be exposed to the outside of the case 100 with the substrate 200 being accommodated within the case 100. Through the connector 220, the semiconductor device 10 may transmit and receive electrical signals (for example, a control signal, a data input and output signal, and a power signal) to and from the external device.

The case 100 may form an appearance of the semiconductor device 10 and an internal space where the substrate 200 is accommodated may be formed therewithin. For example, the case 100 may include an upper frame and a lower frame which are in a flat form and a plurality of side frames connecting the upper frame and the lower frame.

In some implementations, the case 100 may have a mono-frame structure in which the upper frame, the lower frame, and the side frames are formed integrally. The case 100 with the mono-frame structure may be fabricated rapidly and efficiently using an extrusion manner of a metal material. However, the structure of the case 100 is not limited to the above description and may also have a form in which the upper frame and the lower frame are combined with each other.

The case 100 may be fabricated from a material with high heat conductivity so that heat generated in the electronic elements 210 disposed within the case 100 may be appropriately discharged outside the case 100. The case 100 may consist of a single material and may also consist of a combination of different materials. For example, the case 100 may include metal, carbon-based material, polymer, or a combination thereof.

In FIG. 2, the substrate 200 may be inserted into the case 100 while being seated on a support bracket 300. The support bracket 300 may be a movable substrate support structure for supporting the substrate 200 and may enable the substrate 200 to be easily inserted into the case 100 while protecting the substrate 200. The support bracket 300 may include a material with excellent structural rigidity and high heat conductivity, for example, metal, carbon-based material, polymer, or a combination thereof.

The support bracket 300 may be inserted by sliding inside the case 100 to be coupled to the case 100. As the support bracket 300 is fixed to the case 100, the substrate 200 seated on the support bracket 300 may also be fixed and accommodated within the case 100.

The support bracket 300 may move by sliding in a first direction (D1 direction) from one end portion of the case 100 toward another end portion to be coupled to the case 100. For example, in FIG. 2, a first opening part 110 may be formed at the one end portion of the case 100 in the first direction (D1 direction), and a second opening part 120 may be formed at the another end portion of the case 100 in the first direction (D1 direction). The support bracket 300 may be inserted in the first direction (D1 direction) through the first opening part 110 of the case 100 to be coupled to the case 100.

The support bracket 300 may be mechanically interlocked with the case 100 and fixed. In some implementations, the support bracket 300 may be screwed together through a coupling hole 130 provided in the case 100 or may be fixed by adhering through an adhesive member. However, a manner of coupling between the support bracket 300 and the case 100 is not limited to the above description and may be any manners that may fix the support bracket 300 to the case 100.

In FIG. 2, as inserting the support bracket 300 into the case 100 in the first direction (D1 direction) is completed, a flange part 310 formed at an end portion of the support bracket 300 may close the first opening part 110 of the case 100.

In FIG. 2, an auxiliary bracket 400 may be coupled to the second opening part 120 of the case 100. For example, the auxiliary bracket 400 may be inserted by sliding into and coupled to the second opening part 120 of the case 100 in an opposite direction to an insertion direction (for example, D1 direction) of the support bracket 300. The auxiliary bracket 400 may be mechanically interlocked with the case 100 and fixed. In some implementations, the auxiliary bracket 400 may be screwed together through the coupling hole 130 provided in the case 100 or may be fixed by adhering through an adhesive member. However, a manner of coupling between the auxiliary bracket 400 and the case 100 is not limited to the above description and may be any manners that may fix the auxiliary bracket 400 to the case 100.

In FIG. 2, a connector hole 410 configured to enable the connector 220 to be exposed may be disposed at the auxiliary bracket 400. However, the connector 220 may be disposed at various locations on the substrate 200, and corresponding thereto, a position of the connector hole 410 may also be variously changed. For example, based on the position of the connector 220, the connector hole 410 may be formed at the case 100 or the support bracket 300.

In some implementations, the semiconductor device 10 may include a heat dissipation member 500 for smooth heat dissipation of the electronic elements 210 disposed on the substrate 200. The heat dissipation member 500 may be disposed above the substrate 200 to be in contact with the one or more electronic elements 210 mounted on the substrate 200. For example, the heat dissipation member 500 may be disposed to be in physical and thermal contact with an upper surface of the one or more electronic elements 210 mounted on the substrate 200 and may be configured to absorb and discharge heat generated in the electronic elements 210 outwards.

The heat dissipation member 500 may include a metal material with excellent heat conductivity or a thermal interface material (TIM). For example, the heat dissipation member 500 may be a member of a pad type or a sheet type consisting of the TIM.

In FIG. 2, with the support bracket 300 coupled to the case 100, the heat dissipation member 500 may have a state of being in contact with each of the case 100 and the electronic elements 210 of the substrate 200. For example, with the support bracket 300 coupled to the case 100, one surface of the heat dissipation member 500 may be in thermal contact with the electronic elements 210 and another surface of the heat dissipation member 500 may be in thermal contact with an inner surface of the case 100. As the heat dissipation member 500 is disposed between the electronic elements 210 and the case 100, heat generated in the electronic elements 210 may be rapidly discharged outside the semiconductor device 10 through the heat dissipation member 500 and through the case 100.

In FIGS. 1 and 2, the semiconductor device 10 may have a structure of an inclined surface 420 that may cause the heat dissipation member 500 disposed above the substrate 200 to come into close contact with the inner surface of the case 100 while the support bracket 300 is inserted into the case 100. For example, the support bracket 300 may be inserted by sliding into the case 100 with a predetermined clearance space being formed between the heat dissipation member 500 and the case 100 and may slightly move toward a surface facing the inclined surface 420 in the case 100 as climbing up the inclined surface 420 provided within the case 100 while being inserted. Accordingly, the support bracket 300 may be coupled to the case 100 with the heat dissipation member 500 and the case 100 being in close contact with each other.

Through the structure of the inclined surface 420 as above, the semiconductor device 10 may prevent the heat dissipation member 500 from being damaged by rubbing on the inner surface of the case 100 while the substrate 200 and the support bracket 300 supporting the substrate 200 are inserted into the case 100. In addition, by causing the heat dissipation member 500 to be in sufficiently close contact with the case 100 in a state in which inserting the support bracket 300 into the case 100 is completed, heat dissipation efficiency may be increased.

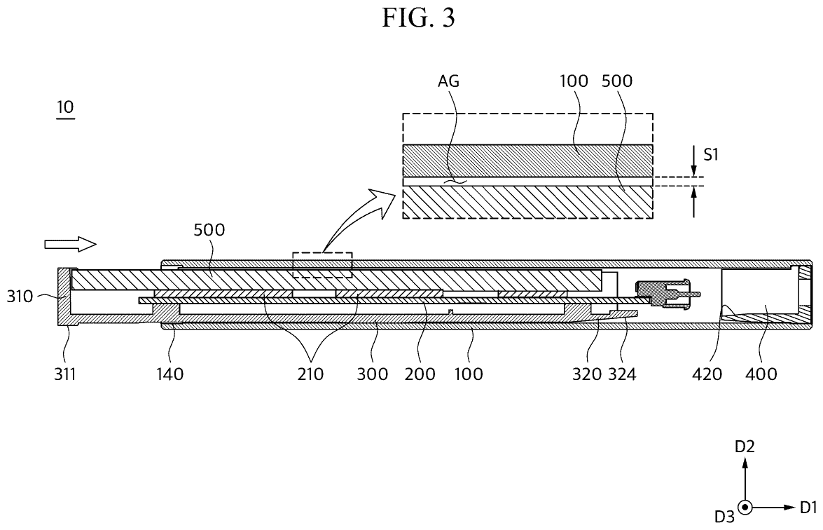

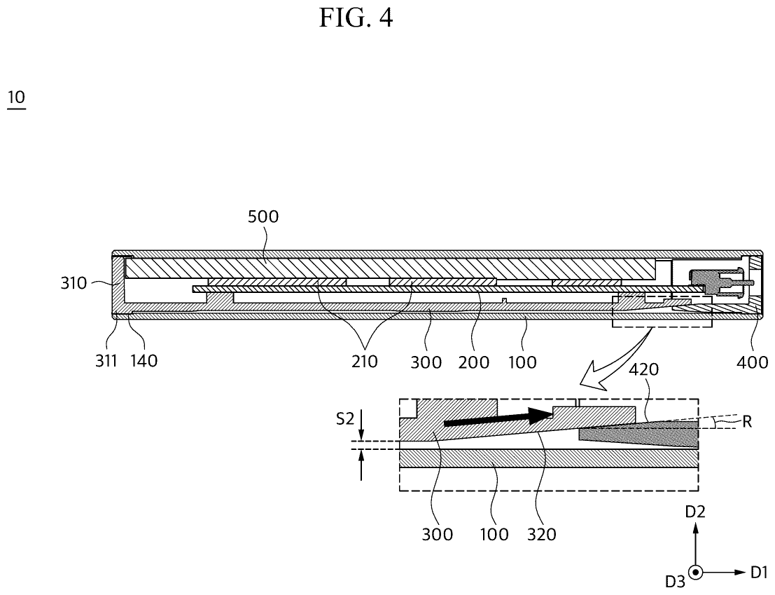

Hereinafter, a coupling structure of the inclined surface 420 provided in the semiconductor device 10 is described in more detail with reference to FIGS. 3 and 4.

FIG. 3 is an example cross-sectional view showing an example of a state before the support bracket 300 is coupled to the case 100 in the semiconductor device 10 according to some implementations. FIG. 4 is an example cross-sectional view showing an example of a state in which the support bracket 300 is coupled to the case 100 in the semiconductor device 10 according to some implementations.

Since the semiconductor device 10 of FIGS. 3 and 4 may correspond to the semiconductor device 10 of FIGS. 1 and 2, a description overlapping those with respect to FIGS. 1 and 2 may be omitted.

In some implementations, the support bracket 300 may move by sliding in the first direction (D1 direction) while supporting the substrate 200 to be coupled to the case 100. For example, the inclined surface 420 may be formed within the case 100. For example, in FIGS. 3 and 4, the inclined surface 420 configured to be in contact with the support bracket 300 may be formed at a portion disposed inside the case 100 in the auxiliary bracket 400. The inclined surface 420 may be formed to be inclined in both the first direction (D1 direction) which is a sliding direction of the support bracket 300 and the second direction (D2 direction) from a lower surface of the case 100 toward an upper interior surface of the case 100 (e.g., a ceiling of the space inside the case 100).

The support bracket 300 may move from a first position of not being in contact with the inclined surface 420 to a second position of being pressed by the inclined surface 420 while moving by sliding in the first direction (D1 direction). For example, FIG. 3 may be a diagram showing a state of the support bracket 300 at the first position and FIG. 4 may be a diagram showing a state of the support bracket 300 at the second position.

In FIG. 3, the support bracket 300 on which the substrate 200 is seated may move by sliding inside the case 100 in the first direction (D1 direction) at the first position of being spaced apart from the inclined surface 420. In this case, the support bracket 300 may move by sliding along the lower surface of the case 100 with an air gap AG being formed between the heat dissipation member 500 disposed above the substrate 200 and the inner surface of the case 100. The air gap AG may refer to a clearance space formed between the heat dissipation member 500 and the inner surface of the case 100. For example, when the support bracket 300 is located at the first position, the air gap AG with a spacing S1 of about 0.2 millimeters (mm) may be formed between an upper surface of the heat dissipation member 500 and the inner surface of the case 100. As above, as the air gap AG is formed between the heat dissipation member 500 and the case 100 while the support bracket 300 is inserted into the case 100, damage to the heat dissipation member 500 or the case 100 or displacement out of position of the heat dissipation member 500 may be prevented from occurring by friction between the heat dissipation member 500 and the inner surface of the case 100 while the support bracket 300 is inserted into the case 100.

However, the air gap AG may act as an insulation structure within the case 100 and thus may be removed in a state in which assembling the substrate 200 and the support bracket 300 into the case 100 is completed. The semiconductor device 10 according to various example embodiments of the present disclosure may remove the air gap AG through the structure of the inclined surface 420 provided within the case 100 and may cause the heat dissipation member 500 to be in close contact with the case 100.

In FIG. 4, the support bracket 300 may move by sliding to the second position to be coupled to the case 100. While moving by sliding from the first position to the second position, the support bracket 300 may slide up along the inclined surface 420 disposed inside the case 100 by external force that inserts the support bracket 300 in the first direction (D1 direction). For example, the support bracket 300 may move by sliding inside the case 100 with the substrate 200 being seated on one surface (for example, an upper surface) thereof, and in this process, another surface (for example, a lower surface) of the support bracket 300 may slide and climb up the inclined surface 420. Accordingly, the support bracket 300 may slightly rise opposite to the lower surface of the case 100 while moving from the first position to the second position.

For example, in FIG. 4, the support bracket 300 may climb up the inclined surface 420 of the auxiliary bracket 400 and rise in the second direction (D2 direction) while moving by sliding, and thus, a predetermined spacing S2 may be formed between the lower surface of the support bracket 300 and the case 100. Accordingly, the air gap AG between the heat dissipation member 500 and the case 100 may be removed and the upper surface of the heat dissipation member 500 may come into close contact with the inner surface of the case 100.

In some implementations, the rising width S2 of the support bracket 300 by the inclined surface 420 may be greater than the spacing S1 of the air gap AG, and in this case, the heat dissipation member 500 may have a slightly compressed state while the support bracket 300 is coupled to the case 100. For example, the support bracket 300 may slightly move by sliding in the first direction (D1 direction) by external force even after the heat dissipation member 500 is in contact with the inner surface of the case 100, and accordingly, may be coupled to the case 100 in a state of being pressed in the second direction (D2 direction) by the inclined surface 420. In other words, at the second position, the support bracket 300 and the heat dissipation member 500 may be in a state pressed by a predetermined pressure in the second direction (D2 direction) by the inclined surface 420.

For example, when the air gap AG of about 0.2 mm is formed when the support bracket 300 is at the first position and the support bracket 300 moves to the second position to rise by about 0.4 mm toward the upper interior surface of the case 100 compared to the first position, the heat dissipation member 500 may be in close contact with the upper interior surface of the case 100 with the thickness thereof compressed by about 0.2 mm. As the heat dissipation member 500 is compressed, a TIM included in at least a portion of the heat dissipation member 500 may be compressed and heat dissipation efficiency may be maximized. However, in some implementations, the air gap AG, the rising width of the support bracket 300, and the compressed degree of the heat dissipation member 500 may be changed and implemented in various manners, in addition to the above-described numerical values. For example, the rising width of the support bracket 300 may be any widths that may remove the air gap AG between the heat dissipation member 500 and the case 100.

In particular, in the semiconductor device 10 having the case 100 fabricated in the mono-frame form, the coupling structure of the inclined surface 420 of the semiconductor device 10 may effectively prevent damage to the heat dissipation member 500 by friction during the assembly process and may also secure sufficiently close contact between the heat dissipation member 500 and the case 100 after assembly completion.

In FIGS. 3 and 4, in order for the support bracket 300 to climb up the inclined surface 420 more smoothly, a portion in contact with the inclined surface 420 in the support bracket 300 may be formed with a chamfered structure or a curved structure. For example, when a portion in contact with the inclined surface 420 and pressed by the inclined surface 420 in the support bracket 300 is defined as a pressing part 320, at least a portion of the pressing part 320 may be formed as a chamfered surface 324 or a curved surface. The chamfered surface 324 or the curved surface may decrease friction force between the support bracket 300 and the inclined surface 420 and enable the support bracket 300 to stably enter onto the inclined surface 420 and enable the support bracket 300 to climb up the inclined surface 420 more smoothly.

Meanwhile, in some implementations, an inclined angle of the inclined surface 420 may be appropriately changed and implemented. For example, based on the lower surface (an inner bottom surface) of the case 100, the inclined angle of the inclined surface 420 may be greater than 0 degree (°) and less than or equal to 30° or, for example, may be about 10°. However, the inclined angle of the inclined surface 420 is not limited to the above-described range of values and may be changed and implemented at various degrees enough for the support bracket 300 to slide up smoothly.

The support bracket 300 may be coupled to the case 100 at the second position while closing the first opening part 110 of the case 100. For example, as the support bracket 300 is located at the second position, the flange part 310 disposed at an edge of the support bracket 300 may close the first opening part 110 of the case 100.

The support bracket 300 may include a protrusion part 311 that is disposed at the flange part 310 and protrudes further than an opposite surface (for example, the lower surface) to a surface (for example, the upper surface) on which the substrate 200 is seated of the support bracket 300. The protrusion part 311 may be in contact with the case 100 to support a lower portion of the support bracket 300 and may enable the support bracket 300 to stably maintain a state of a rise due to the inclined surface 420.

In FIGS. 3 and 4, a step part 140 that restricts a movement of the protrusion part 311 so that the protrusion part 311 may not enter any further in the first direction (D1 direction) may be formed at an inner side of the first opening part 110 of the case 100. The step part 140 may be in contact with the protrusion part 311 in the first direction (D1 direction), preventing the protrusion part 311 from being inserted beyond a certain extent into the case 100. This allows the step part 140 to function as a type of stopper, preventing the support bracket 300 from being inserted further than necessary.

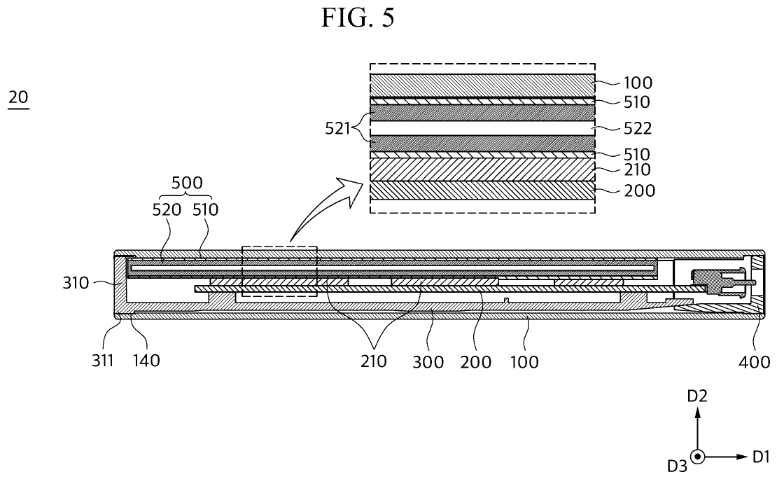

Hereinafter, with reference to FIGS. 5 to 12, semiconductor devices 20, 30, and 40 according to some implementations are described.

FIG. 5 is an example cross-sectional view of an example of a semiconductor device according to some implementations. In some implementations, the heat dissipation member 500 of a semiconductor device 20 may include a vapor chamber 520 including a metal material. For example, in FIG. 5, the heat dissipation member 500 may have a structure in which a heat dissipation pad 510 consisting of a TIM is attached on an outer surface of the vapor chamber 520.

The vapor chamber 520 may include a metal plate 521 and a refrigerant space 522 formed within the metal plate 521. The metal plate 521 may include at least one of copper, aluminum, stainless steel, and graphite but may include various metal materials with high heat conductivity in addition thereto. The refrigerant space 522 may accommodate various refrigerants such as air, liquid nitrogen, and water and may be configured to carry heat using phase transformation of these refrigerants. In some implementations, the refrigerant space 522 may have a vacuum state. The vapor chamber 520 may enable the heat dissipation member 500 to have overall uniform heat distribution by preventing heat concentration (in other words, hot spot) from occurring at a specific portion of the heat dissipation member 500. Accordingly, the heat dissipation efficiency of the heat dissipation member 500 may be maximized.

In FIG. 5, the heat dissipation pad 510 may be interposed between the vapor chamber 520 and the case 100 or between the vapor chamber 520 and the electronic elements 210. The heat dissipation pad 510 may allow rapid heat transfer between the vapor chamber 520 and the case 100 or between the vapor chamber 520 and the electronic elements 210 and may perform a role of buffering when the metal material of the vapor chamber 520 bumps directly against the electronic elements 210 or the case 100.

Meanwhile, other technical features excluding the heat dissipation member 500 in the semiconductor device 20 of FIG. 5 may be referenced in the descriptions of the semiconductor device 10 of FIGS. 1 to 4.

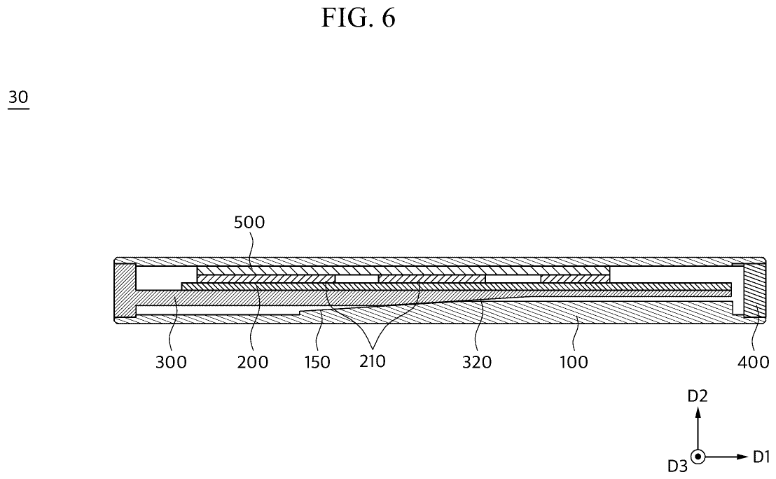

FIG. 6 is an example cross-sectional view of an example of a semiconductor device according to some implementations. In FIG. 6, an inclined surface 150 that pushes up and presses the support bracket 300 may be formed at the inner bottom surface of the case 100. For example, the case 100 may be fabricated with the inclined surface 150 formed at the bottom surface thereof. Accordingly, the inclined surface 150 that is structurally more robust may be formed.

In FIG. 6, the plurality of electronic elements 210 may be disposed at a specific region (hereinafter referred to as an element region) of the substrate 200, and the inclined surface 150 within the case 100 may be formed to press a location corresponding to the element region of the substrate 200 in the support bracket 300. For example, the inclined surface 150 may be formed gradually across a wide region of the inner bottom surface of the case 100, and the pressing part 320 in contact with the inclined surface 150 in the support bracket 300 may be formed at a location facing the element region of the substrate 200 in the second direction (D2 direction). As the support bracket 300 moves by sliding in the first direction (D1 direction), the pressing part 320 may be in contact with the inclined surface 150 and pressed, and the pressing part 320 may transfer this pressure intensively to a portion facing the element region of the substrate 200 in the heat dissipation member 500. Accordingly, the portion facing the element region in the heat dissipation member 500 may be intensively pressed and partially become in close contact with the inner surface of the case 100 more strongly, and the heat dissipation efficiency of the element region may be maximized.

Meanwhile, other technical features excluding the positions of the inclined surface 150 and the pressing part 320 in the semiconductor device 30 of FIG. 6 may be referenced in the descriptions of the semiconductor devices 10 and 20 of FIGS. 1 to 5.

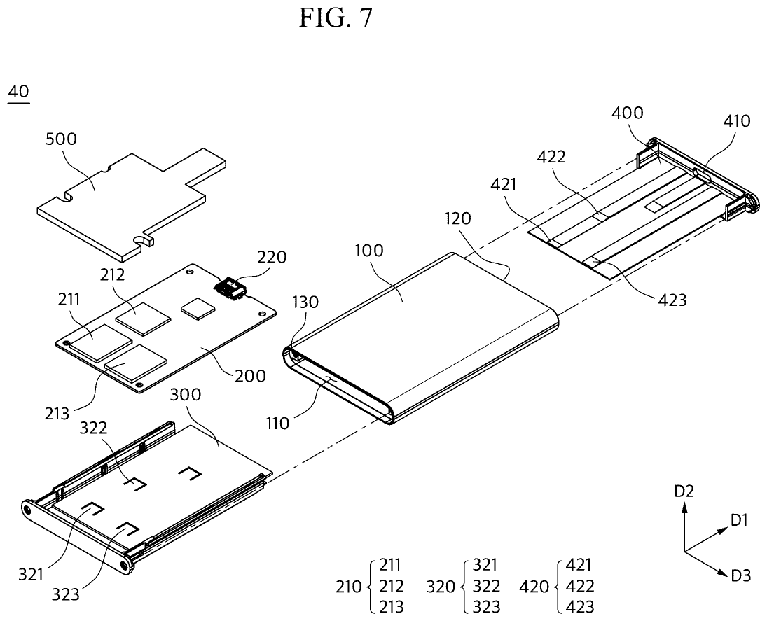

In some implementations, the semiconductor device 40 may include a plurality of inclined surfaces 420. Hereinafter, with reference to FIGS. 7 to 12, the semiconductor device 40 having the plurality of inclined surfaces 420 is described.

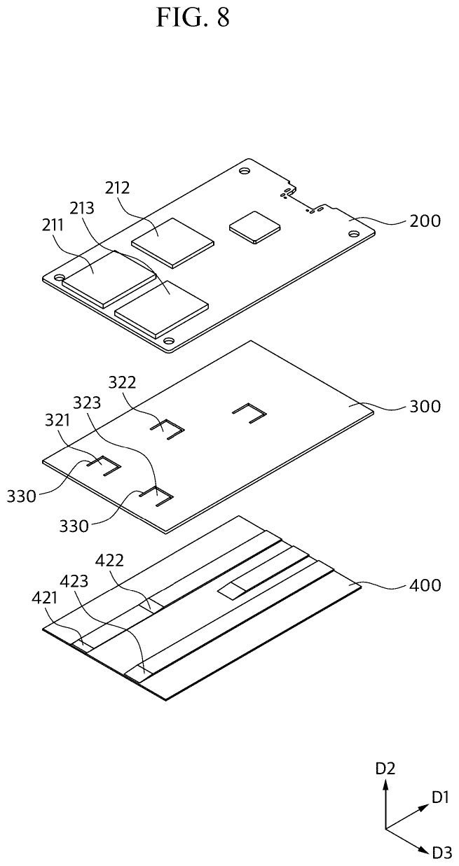

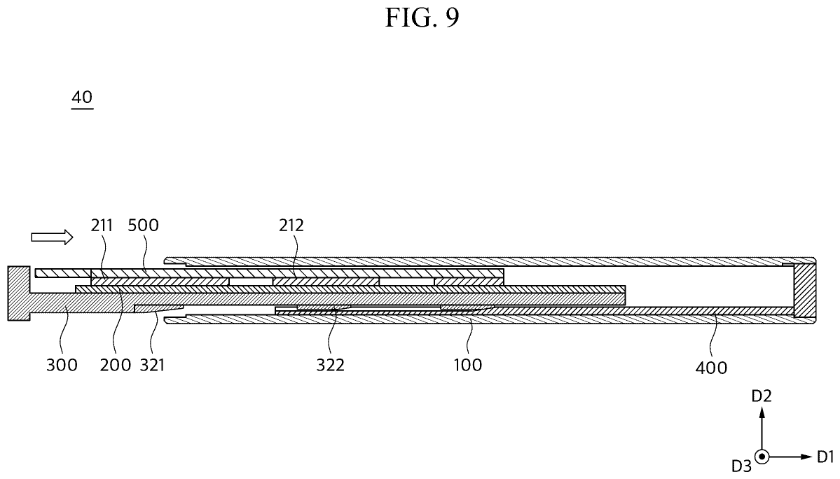

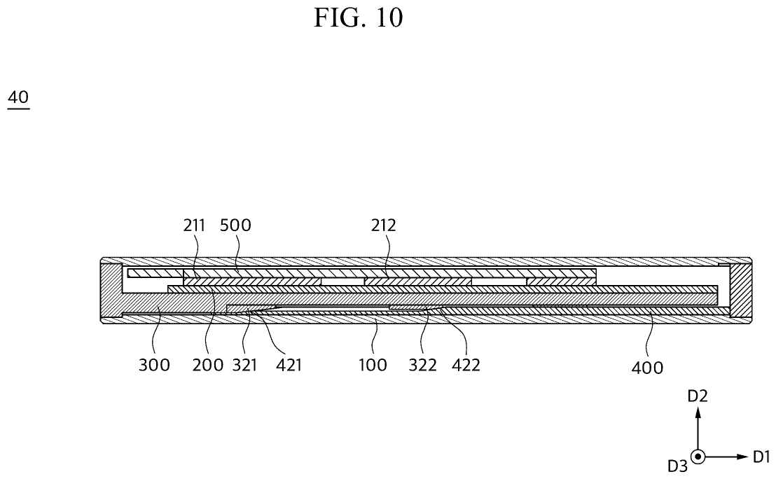

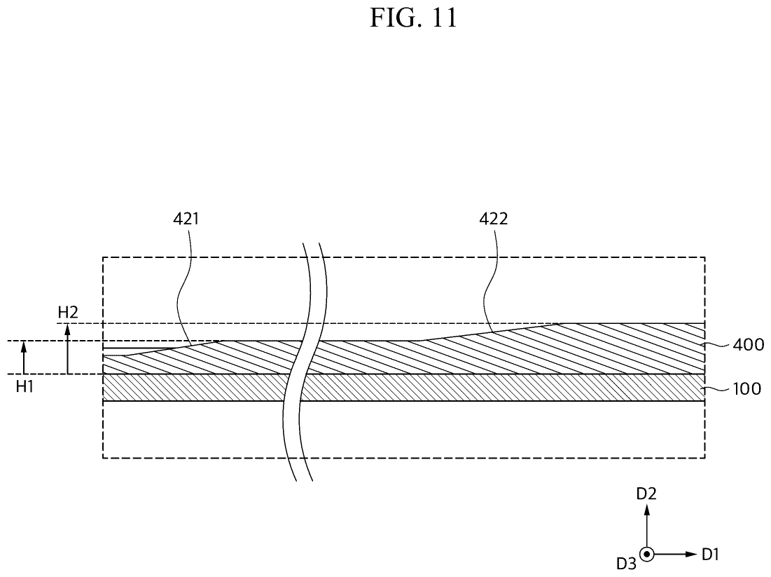

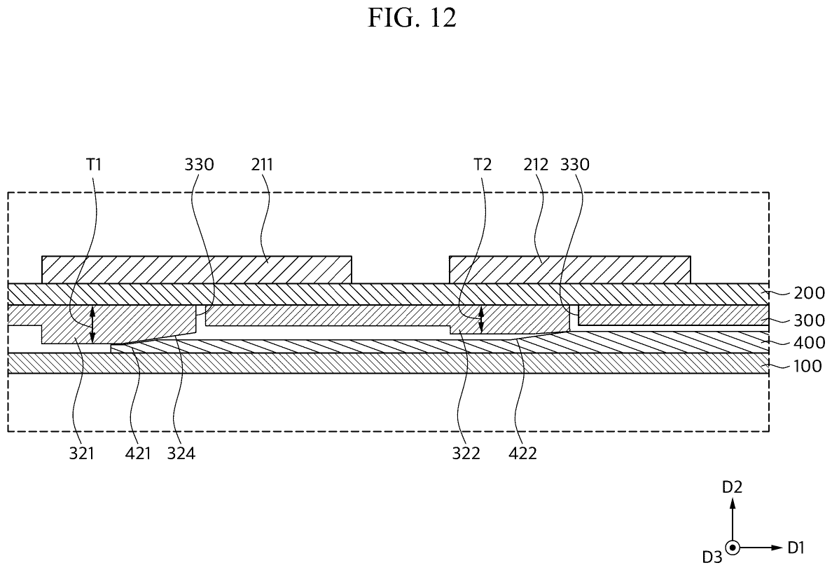

FIG. 7 is an exploded perspective view of an example of a semiconductor device according to some implementations. FIG. 8 is a reference diagram for illustrating an example of an arrangement of the pressing part 320 and the inclined surface 420 according to some implementations. FIG. 9 is an example cross-sectional view of an example of a state before the support bracket 300 is coupled to the case 100 in the semiconductor device 40 according to some implementations. FIG. 10 is an example cross-sectional view of an example of a state in which the support bracket 300 is coupled to the case 100 in the semiconductor device 40 according to some implementations. FIG. 11 illustrates a portion of a cross-sectional view of the auxiliary bracket 400 included in the semiconductor device 40 according to some implementations. FIG. 12 illustrates a portion of a cross-sectional view of the semiconductor device 40 according to some implementations.

In some implementations, the plurality of electronic elements 210 may be disposed on the substrate 200 of the semiconductor device 40. For example, in FIGS. 7 and 8, the plurality of electronic elements 210 may be disposed to be spaced apart in the first direction (D1 direction) or a third direction (D3 direction) on the substrate 200.

The semiconductor device 40 may include a plurality of pressing parts 320 and the plurality of inclined surfaces 420 corresponding thereto in order to press locally a portion facing the plurality of electronic elements 210 in the heat dissipation member 500 and make close contact. For example, the pressing parts 320 may be individually disposed at a portion corresponding to a location of each of the electronic elements 210 in the support bracket 300 on which the substrate 200 is seated. In addition, the plurality of inclined surfaces 420 may be formed in the auxiliary bracket 400 to appropriately push up and press each of the pressing parts 320.

In FIGS. 7 and 8, the semiconductor device 40 may include a first semiconductor element 211 and a second semiconductor element 212 which are disposed along the first direction (D1 direction) which is the sliding direction of the support bracket 300 and a third semiconductor element 213 disposed to be spaced apart from the first semiconductor element 211 in the third direction (D3 direction).

The substrate 200 may be seated on the support bracket 300, and the support bracket 300 may include a first pressing part 321 overlapping with the first semiconductor element 211 in the second direction (D2 direction), a second pressing part 322 overlapping with the second semiconductor element 212 in the second direction (D2 direction), and a third pressing part 323 overlapping with the third semiconductor element 213 in the second direction (D2 direction).

While the support bracket 300 moves by sliding in the first direction (D1 direction), each of the first pressing part 321, the second pressing part 322, and the third pressing part 323 may be in contact with the different inclined surfaces 420 and pressed. For example, a first inclined surface 421 in contact with the first pressing part 321, a second inclined surface 422 in contact with the second pressing part 322, and a third inclined surface 423 in contact with the third pressing part 323 may be disposed in the auxiliary bracket 400.

The plurality of inclined surfaces 420 may be formed in the auxiliary bracket 400 as in FIGS. 7 and 8. However, the position of the inclined surfaces 420 being formed is not limited to the above description. For example, the plurality of inclined surfaces 420 may also be formed on the inner bottom surface of the case 100 as described above through FIG. 6.

In FIGS. 9 and 10, the support bracket 300 may move from a first position where the pressing parts 320 are not in contact with the inclined surfaces 420 to a second position where the pressing parts 320 are pressed by the inclined surfaces 420 while moving by sliding in the first direction (D1 direction). For example, FIG. 9 may be a diagram showing a state of the support bracket 300 at the first position and FIG. 10 may be a diagram showing a state of the support bracket 300 at the second position.

In FIG. 10, with the support bracket 300 coupled to the case 100, the first pressing part 321 and the first semiconductor element 211 may be disposed at a location facing the first inclined surface 421 in the second direction (D2 direction) parallel to a thickness direction of the substrate 200. The first pressing part 321 may be pressed by the first inclined surface 421 and may transfer this pressure to a portion facing the first semiconductor element 211 in the heat dissipation member 500. Accordingly, a vertical pressure (for example, a pressure in D2 direction) may be applied locally to the portion facing the first semiconductor element 211 in the heat dissipation member 500 and the corresponding portion may be in close contact with the inner surface of the case 100.

Further, in ome implementations, with the support bracket 300 coupled to the case 100, the second pressing part 322 and the second semiconductor element 212 may be disposed at a location facing the second inclined surface 422 in the second direction (D2 direction) parallel to the thickness direction of the substrate 200. Identically to the description of the first pressing part 321, a pressure that the second inclined surface 422 applies to the second pressing part 322 may be transferred to the heat dissipation member 500. Accordingly, a vertical pressure (for example, a pressure in D2 direction) may be applied locally to a portion facing the second semiconductor element 212 in the heat dissipation member 500 and the corresponding portion may be in close contact with the inner surface of the case 100.

As above, by locally applying pressure to a portion corresponding to each of the electronic elements 210 in the heat dissipation member 500, including the plurality of pressing parts 320 and the plurality of inclined surfaces 420, the semiconductor device 40 may enable the portion to be in close contact with the inner surface of the case 100. Accordingly, an optimum heat transfer path from each of the electronic elements 210 to the case 100 may be formed.

In order for interference not to be generated between the plurality of pressing parts 320 and the plurality of inclined surfaces 420 while the support bracket 300 moves by sliding from the first position to the second position, those disposed along the first direction (D1 direction) among the plurality of pressing parts 320 and those disposed along the first direction (D1 direction) among the plurality of inclined surfaces 420 may have different thicknesses or heights (here, the thickness or height refers to a length in the second direction (D2 direction)).

For example, in FIGS. 11 and 12, in the first inclined surface 421 and the second inclined surface 422 which are disposed along the first direction (D1 direction), a height H1 of a highest point of the first inclined surface 421 may be lower than a height H2 of a highest point of the second inclined surface 422 based on the bottom surface of the case 100. As above, as the first inclined surface 421 is formed to be lower, the second pressing part 322 encountering first the first inclined surface 421 while the support bracket 300 moves by sliding along the first direction (D1 direction) may move smoothly to the second inclined surface 422 without interference from the first inclined surface 421.

Meanwhile, in order to compensate for a height difference between the first inclined surface 421 and the second inclined surface 422, in the first pressing part 321 and the second pressing part 322 which are disposed along the first direction (D1 direction), a thickness T1 of the first pressing part 321 may be formed to be thicker than a thickness T2 of the second pressing part 322. For example, referring to FIGS. 11 and 12 together, the thickness T1 of the first pressing part 321 in contact with the first inclined surface 421 of which the height H1 of the highest point is relatively low may be thicker than the thickness T2 of the second pressing part 322 in contact with the second inclined surface 422 of which the height H2 of the highest point is relatively high. Accordingly, the plurality of pressing parts 320 may be in sufficient contact with the inclined surfaces 420 having each different height.

The height of the inclined surfaces 420 or the thickness of the pressing parts 320 may be appropriately changed and implemented. For example, the height of the inclined surfaces 420 or the thickness of the pressing parts 320 in the semiconductor device 40 may be formed in a manner that a portion in contact with each of the electronic elements 210 in the heat dissipation member 500 has different compression rate from each other. For example, the first inclined surface 421 may press the first pressing part 321 and enable a portion in contact with the first semiconductor element 211 in the heat dissipation member 500 to be in close contact with the case 100 in a state of being compressed at a first compression rate. In addition, the second inclined surface 422 may press the second pressing part 322 and enable a portion in contact with the second semiconductor element 212 in the heat dissipation member 500 to be in close contact with the case 100 in a state of being compressed at a second compression rate different from the first compression rate. Accordingly, as the heat dissipation member 500 is in close contact locally at a region facing each of the electronic elements 210 by an optimum pressure, a heat dissipation structure optimized for a thermal property of each of the electronic elements 210 may be implemented.

In order for the support bracket 300 to climb up the plurality of inclined surfaces 420 more smoothly, at least one of the plurality of pressing parts 320 may include a chamfered structure or a curved structure. For example, referring to FIG. 12, the chamfered surface 324 or a curved surface may be formed at edges of the first pressing part 321 and the second pressing part 322 in the first direction (D1 direction).

The pressing parts 320 of the support bracket 300 may be configured to elastically deform to move relatively to other portions of the support bracket 300 within a predetermined range. For example, in FIGS. 8 and 12, a slit 330 may be formed along edges of the pressing parts 320, and the pressing parts 320 may be connected to other portions of the support bracket 300 through an edge where the slit 330 is not formed. The slit 330 may have a structure penetrating the support bracket 300. When the inclined surfaces 420 press the pressing parts 320 as the support bracket 300 moves by sliding in the first direction (D1 direction), the pressing parts 320 may elastically deform while rotating about a portion where the slit 330 is not formed, which is a rotation axis, and move relatively to other portions of the support bracket 330. As a structure of the slit 330 is formed along the edges of the pressing parts 320, the pressing parts 320 may apply locally a vertical pressure (for example, a pressure in D2 direction) to the heat dissipation member 500 disposed above the substrate 200 more effectively.

Meanwhile, other technical features excluding the features regarding the inclined surfaces 420 and the pressing parts 320 in the semiconductor device 40 of FIGS. 7 to 12 may be referenced in the descriptions with reference to FIGS. 1 to 6.

According to some implementations, the semiconductor devices 10, 20, 30, and 40 having a simple assembly structure of coupling by sliding the heat dissipation member 500 and the support bracket 300 on which the substrate 200 is seated to the case 100 may be implemented.

According to some implementations, damage to parts or assembly defects due to friction between the heat dissipation member 500 and the case 100 while the support bracket 300 moves by sliding may be prevented. In addition, by allowing the heat dissipation member 500 to be in sufficiently close contact with the case 100 after assembly through the structure of the inclined surface 420 within the case 100, heat dissipation efficiency may be enhanced.

Since the air gap AP may be appropriately formed or removed based on the position of the support bracket 300 using the structure of the inclined surface 420, the sliding coupling structure of the support bracket 300 may be effectively implemented even when the case 100 is formed as an integral mono-frame type other than a combination of a plurality of individual frames. Accordingly, the semiconductor devices 10, 20, 30, and 40 with all of ease of assembly, processibility, and heat dissipation performance enhanced may be implemented.

According to some implementations, it is possible to implement a semiconductor device having excellent thermal stability as well as superior assemblability and processability.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a case defining an internal space;
a support bracket configured to slide within the internal space along a first direction from a first end portion of the case toward a second end portion of the case;
a substrate on a surface of the support bracket;
one or more semiconductor elements mounted on the substrate;
a heat dissipation member between an inner surface of the case and the one or more semiconductor elements; and
one or more inclined surfaces within the case,
wherein the one or more inclined surfaces is configured to, based on the support bracket sliding in the internal space along the first direction on the one or more inclined surfaces, move the surface of the support bracket toward the inner surface of the case that faces the surface of the support bracket.

2. The semiconductor device of claim 1, comprising an auxiliary bracket coupled to the case,
wherein the one or more inclined surfaces provided at the auxiliary bracket.

3. The semiconductor device of claim 2,
wherein the support bracket is coupled to a first opening defined at the first end portion of the case, and
wherein the auxiliary bracket is coupled to a second opening defined at the second end portion of the case.

4. The semiconductor device of claim 1,
wherein the support bracket includes a pressing part configured to be pressed by the one or more inclined surfaces based on the support bracket sliding along the first direction, and
wherein the pressing part includes a chamfered surface or a curved surface at an edge of the pressing part in the first direction.

5. The semiconductor device of claim 4,
wherein the support bracket includes a protrusion spaced apart from the pressing part in an opposite direction to the first direction, and
wherein the protrusion protrudes on an opposite surface of the surface of the support bracket.

6. The semiconductor device of claim 5, wherein the case includes:
a first opening into which the support bracket is configured to be inserted; and
a step on an inner surface of the first opening and configured to be interlocked with the protrusion to thereby restrict a movement of the protrusion.

7. The semiconductor device of claim 1,
wherein the one or more semiconductor elements include a first semiconductor element and a second semiconductor element arranged along the first direction, and
wherein the one or more inclined surfaces include:
a first inclined surface facing the first semiconductor element in a thickness direction of the substrate; and
a second inclined surface facing the second semiconductor element in the thickness direction of the substrate.

8. The semiconductor device of claim 7, wherein a height of a highest point of the first inclined surface is lower than a height of a highest point of the second inclined surface.

9. The semiconductor device of claim 7,
wherein the support bracket includes:
a first pressing part configured to contact the first inclined surface; and
a second pressing part configured to contact the second inclined surface, and
wherein a thickness of the first pressing part is greater than a thickness of the second pressing part.

10. The semiconductor device of claim 9,
wherein the support bracket includes a slit defined along edges of the first pressing part and the second pressing part, and
wherein the first pressing part and the second pressing part are configured to contact the first inclined surface and the second inclined surface to thereby deform, respectively.

11. The semiconductor device of claim 1,
wherein the heat dissipation member includes a heat dissipation pad having a thermal interface material and being in contact with the one or more semiconductor elements, and
wherein the heat dissipation pad is configured to contact the case based on the support bracket being coupled to the case.

12. The semiconductor device of claim 1, wherein the heat dissipation member includes:
a vapor chamber including a refrigerant space; and
a heat dissipation pad interposed between the vapor chamber and the case,
wherein the heat dissipation pad includes a thermal interface material.

13. The semiconductor device of claim 1, wherein the one or more inclined surfaces are defined on a bottom surface within the case.

14. The semiconductor device of claim 1, wherein an inclined angle of the one or more inclined surfaces is greater than 0 degree (°) and less than or equal to 30°.

15. A semiconductor device comprising:
a substrate;
one or more semiconductor elements mounted on the substrate;
a support bracket on which the substrate is mounted;
a case configured to accommodate the support bracket;
a heat dissipation member between an inner surface of the case and the one or more semiconductor elements; and
an inclined surface within the case, the inclined surface being sloped relative to a lower surface of the support bracket,
wherein the support bracket is configured to slide from a first position spaced apart from the inclined surface to a second position in contact with the inclined surface,
wherein the heat dissipation member is spaced apart from the case based on the support bracket being at the first position, and
wherein the heat dissipation member is in contact with the case based on the support bracket being at the second position.

16. The semiconductor device of claim 15,
wherein the support bracket is configured to slide inside the case through an opening defined at a side of the case, and
wherein the support bracket is configured to close the opening of the case at the second position.

17. A semiconductor device comprising:
a substrate;
a first semiconductor element and a second semiconductor element mounted along a first direction on the substrate;
a support bracket on which the substrate is mounted, the support bracket including a first pressing part under the first semiconductor element and a second pressing part under the second semiconductor element;
a case having an opening provided at a side and into which the support bracket is configured to be inserted through the opening in the first direction;
a heat dissipation member having a first surface in contact with the first semiconductor element and the second semiconductor element and a second surface in contact with the case;
a first inclined surface within the case, the first inclined surface configured to move the first pressing part of the support bracket; and
a second inclined surface within the case, the second inclined surface configured to move the second pressing part of the support bracket.

18. The semiconductor device of claim 17, wherein a height of a highest point of the second inclined surface is greater than a height of a highest point of the first inclined surface.

19. The semiconductor device of claim 17, wherein a compression rate of a first portion of the heat dissipation member in contact with the first semiconductor element is different from a compression rate of a second portion of the heat dissipation member in contact with the second semiconductor element.

20. The semiconductor device of claim 17, comprising:
a third semiconductor element spaced apart from the first semiconductor element in a second direction perpendicular to the first direction on the substrate; and
a third inclined surface spaced apart from the first inclined surface in the second direction within the case.
